(19) United States
(12) Patent Application Publication
(10) Pub. No.: US 2025/0239571 A1
(43) Pub. Date: Jul. 24, 2025

(54) SEMICONDUCTOR PACKAGE

(71) Applicant: SAMSUNG ELECTRONICS CO., LTD., Suwon-si (KR)

(72) Inventors: Jaejun Lee, Suwon-si (KR); Juhyeon Kim, Suwon-si (KR); Cheol Kim, Suwon-si (KR)

(73) Assignee: SAMSUNG ELECTRONICS CO., LTD., Suwon-si (KR)

(21) Appl. No.: 18/883,499

(22) Filed: Sep. 12, 2024

(30) Foreign Application Priority Data
Jan. 22, 2024 (KR) 10-2024-0009446

(51) Int. Cl. H01L 25/065; H01L 23/00; H01L 23/31; H01L 23/48

(52) U.S. Cl. CPC H01L 25/0657; H01L 23/481; H01L 24/05; H01L 24/13; H01L 24/14; H01L 24/16; H01L 23/3107; H01L 23/3171; H01L 24/32; H01L 24/73; H01L 2224/0401; H01L 2224/05124; H01L 2224/05557; H01L 2224/05576; H01L 2224/05647; H01L 2224/05666; H01L 2224/13083; H01L 2224/13147; H01L 2224/13166; H01L 2224/1403; H01L 2224/14131; H01L 2224/14135; H01L 2224/14181; H01L 2224/16146; H01L 2224/32145; H01L 2224/73204; H01L 2225/06513

(57) ABSTRACT

A semiconductor package includes a first semiconductor chip including a first substrate having a first front surface and a first rear surface, first front pads, a first interlayer insulating layer between the first front pads and the first substrate, and a first interconnection structure in the first interlayer insulating layer and connected to the first front pads, and a front cover layer on the first interlayer insulating layer and including openings respectively exposing at least a portion of each of the first front pads, where a thermal conductivity of the front cover layer is smaller than a thermal conductivity of the first interlayer insulating layer and a thermal conductivity of the first substrate.

### CROSS-REFERENCE TO RELATED APPLICATION(S)

This application is based on and claims priority to Korean Patent Application No. 10-2024-0009446, filed on Jan. 22, 2024, in the Korean Intellectual Property Office, the disclosure of which is incorporated by reference herein in its entirety.

### BACKGROUND

Example embodiments of the disclosure relate to a semiconductor package.

Semiconductor packages installed in electronic devices may require miniaturization as well as high performance and high capacity. To implement this, research is being conducted into semiconductor packages in which semiconductor chips including through-silicon-vias (TSVs) are stacked in a vertical direction.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor package having improved efficiency in a manufacturing process.

Additional aspects will be set forth in part in the description which follows and, in part, will be apparent from the description, or may be learned by practice of the presented embodiments.

According to an aspect of one or more embodiments, a semiconductor package may include a first semiconductor chip including a first substrate having a first front surface and a first rear surface, first front pads, a first interlayer insulating layer between the first front pads and the first substrate, and a first interconnection structure in the first interlayer insulating layer and connected to the first front pads, a front cover layer on the first interlayer insulating layer and including openings respectively exposing at least a portion of each of the first front pads, first connection pillars respectively in the openings of the front cover layer and respectively connected to the first front pads, a second semiconductor chip including a second substrate having a second front surface and a second rear surface, second front pads facing a first group of the first connection pillars, and through-electrodes in the second substrate and connected to the second front pads, second connection pillars respectively on the second front pads and respectively connected to the first connection pillars of the first group of first connection pillars, an adhesive film layer disposed between the first semiconductor chip and the second semiconductor chip and at least partially surrounding the second connection pillars, a molded layer at least partially covering a second group of the first connection pillars and the second rear surface of the second semiconductor chip, first through-vias in the molded layer and on at least one side of the second semiconductor chip, the first through-vias respectively on the first connection pillars of the second group of the first connection pillars, and connection bumps disposed on the molded layer and electrically connected to the first through-vias and the through-electrodes of the second semiconductor chip, where a thermal conductivity of the front cover layer is smaller than a thermal conductivity of the first interlayer insulating layer and a thermal conductivity of the first substrate.

According to an aspect of one or more embodiments, a semiconductor package may include a first semiconductor chip including a first substrate having a first front surface and first front pads on the first front surface, a second semiconductor chip including a second substrate having a second front surface, second front pads facing the first front pads, and through-electrodes in the second substrate and respectively connected to the second front pads, first connection pillars respectively on the first front pads, a front cover layer at least partially surrounding a side surface of each of the first connection pillars on the first front surface of the first semiconductor chip, second connection pillars respectively on the second front pads and respectively connected to the first connection pillars, an adhesive film layer at least partially surrounding a side surface of each of the second connection pillars on the second front surface of the second semiconductor chip, a molded layer at least partially surrounding the second semiconductor chip on the first semiconductor chip, and connection bumps respectively connected to the through-electrodes of the second semiconductor chip, where a thermal conductivity of the front cover layer is less than 1 W/m·K.

According to an aspect of one or more embodiments, a semiconductor package may include a first semiconductor chip including a first substrate, first front pads, an interlayer insulating layer between the first front pads and the first substrate, and an interconnection structure in the interlayer insulating layer and connected to the first front pads, a second semiconductor chip including a second substrate, and second front pads on the second substrate and facing the first front pads, first connection pillars respectively on the first front pads, a front cover layer filling a space between the first connection pillars, second connection pillars respectively on the second front pads and respectively contacting the first connection pillars, and an adhesive film layer filling a space between the second connection pillars, where the interlayer insulating layer includes a non-metallic inorganic material, the front cover layer and the adhesive film layer includes a polymer organic material.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1A is a cross-sectional view illustrating a semiconductor package according to one or more embodiments;

FIG. 1B is a cross-section plan view taken along line I-I′ of FIG. 1A according to one or more embodiments;

FIG. 1C is a partially enlarged view of portion ‘A’ of FIG. 1A according to one or more embodiments;

FIGS. 2A to 2E are partially enlarged views illustrating a semiconductor package according to one or more embodiments;

FIG. 3 is a cross-sectional view illustrating a semiconductor package according to one or more embodiments;

FIG. 4 is a cross-sectional view illustrating a semiconductor package according to one or more embodiments;

FIG. 5 is a cross-sectional view illustrating a semiconductor package according to one or more embodiments;

FIG. 6 is a cross-sectional view illustrating a semiconductor package according to one or more embodiments;

FIGS. 7A to 7G are views illustrating a process of manufacturing a semiconductor package according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Additionally, ordinal numbers such as “first,” “second,” “third,” or the like may be used as labels for specific elements, steps, operations, directions, or the like to distinguish various elements, steps, operations, directions, or the like from each other. Terms that may not be described using “first,” “second,” or the like in the specification may still be referred to as “first” or “second” in the claims. Additionally, terms referenced by a particular ordinal number (e.g., “first” in a particular claim) may be described elsewhere with a different ordinal number (e.g., “second” in the specification or another claim).

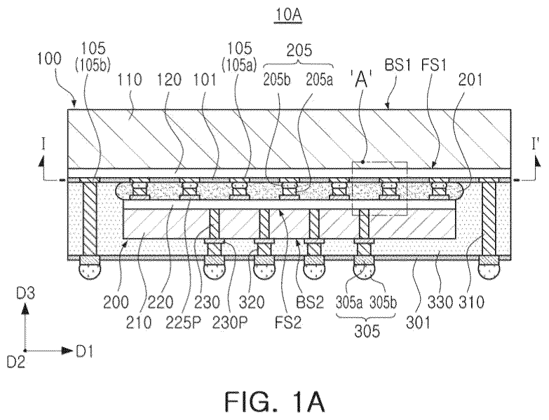

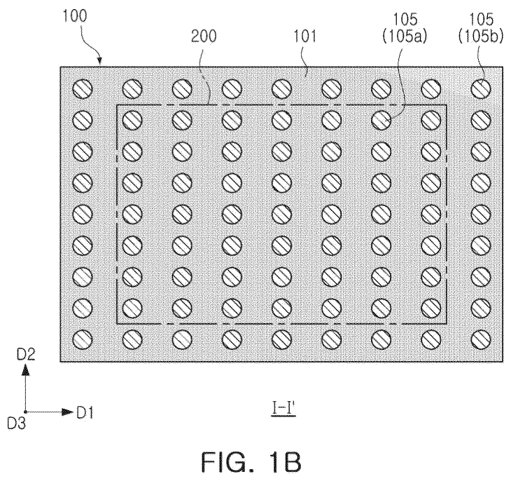

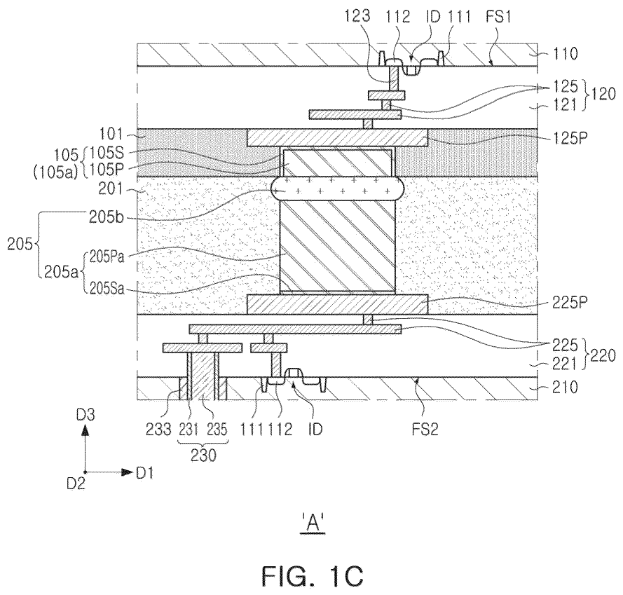

FIG. 1A is a cross-sectional view illustrating a semiconductor package 10A according to one or more embodiments. FIG. 1B is a cross-section plan view taken along line I-I′ of FIG. 1A according to one or more embodiments. FIG. 1C is a partially enlarged view of portion ‘A’ of FIG. 1A according to one or more embodiments.

Referring to FIGS. 1A to 1C, a semiconductor package 10A according to one or more embodiments may include a first semiconductor chip 100, a front cover layer 101, first connection pillars 105, a second semiconductor chip 200, an adhesive film layer 201, and second connection pillars 205. The semiconductor package 10A may further include first through-vias 310, second through-vias 320, a molded layer 330, a protective layer 301, and/or connection bumps 305.

According to one or more embodiments, the first semiconductor chip 100 and the second semiconductor chip 200 may be stacked such that a first circuit layer 120 and a second circuit layer 220, on which an integrated circuit is formed, face each other, thereby minimizing a signal transmission path between the semiconductor chip 100 and the second semiconductor chip 200. The first semiconductor chip 100 and the second semiconductor chip 200 may be logic chips including a central processing unit (CPU), a graphics processing unit (GPU), a field programmable gate array (FPGA), a digital signal processor (DSP), an encryption processor, a microprocessor, a microcontroller, an analog-to-digital converter, etc., or memory chips including a volatile memory (e.g., dynamic random access memory (RAM) (DRAM)), a non-volatile memory (e.g., read-only memory (ROM) and flash memory), etc. For example, the first semiconductor chip 100 may include a logic circuit such as an application specific semiconductor (ASIC), and the second semiconductor chip 200 may include a cache memory circuit that provides cache information to the first semiconductor chip 100. A size of the second semiconductor chip 200 may be smaller than a size of the first semiconductor chip 100. For example, a width of the first semiconductor chip 100 may be greater than a width of the second semiconductor chip 200.

Additionally, in one or more embodiments, the front cover layer 101 may be provided to entirely or at least partially cover one surface (e.g., lower surface) of the first semiconductor chip 100 on which the first connection pillars 105 are disposed. The front cover layer 101 may have relatively low thermal conductivity, to minimize heat loss during a thermocompression bonding process between the first semiconductor chip 100 and the second semiconductor chip 200. As a result, efficiency of a manufacturing process may be improved, and manufacturing costs may be reduced.

The first semiconductor chip 100 may include a first substrate 110 and a first circuit layer 120.

The first substrate 110 may be a semiconductor wafer. The first substrate 110 may include, for example, a semiconductor element such as silicon or germanium, or a compound semiconductor such as silicon carbide (SiC), gallium arsenide (GaAs), indium arsenide (InAs), or indium phosphide (InP). The first substrate 110 may have a first front surface FS1 and a first rear surface BS1. The first substrate 110 may include a conductive region 112 and an isolation region 111 that may be formed on the first front surface FS1. The conductive region 112 may be, for example, a well doped with impurities or a structure doped with impurities. The isolation region 111 may be a device isolation structure having a shallow trench isolation (STI) structure, and may include silicon oxide.

The first circuit layer 120 may be disposed on the first front surface FS1 of the first substrate 110 on which the conductive region 112 is formed. The first circuit layer 120 may include individual devices ID, a first interlayer insulating layer 121, and a first interconnection structure 125.

The individual devices ID may be disposed on the first front surface FS1 of the first substrate 110. The individual devices ID may include, for example, a field-effect transistor (FET) such as a planar FET, a FinFET, etc., a memory device such as a flash memory, a DRAM, a static RAM (SRAM), an electrically erasable programming ROM (EEPROM), a phase-change RAM (PRAM), a magnetoresistive RAM (MRAM), a ferroelectric RAM (FeRAM), a resistive RAM (RRAM), etc., a logic device such as AND, OR, NOT, etc., or various active and/or passive devices such as a large scale integration (LSI) system, a CIS, and micro-electromechanical system (MEMS).

The first interlayer insulating layer 121 may be disposed between first front pads 125P and the first substrate 110. The first interlayer insulating layer 121 may be formed to cover the individual devices ID and the first interconnection structure 125, to electrically isolate the individual devices ID disposed on the first substrate 110. The first interlayer insulating layer 121 may include at least one of a non-metallic inorganic material, for example, silicon oxide (SiO) and silicon nitride (SiN). The first interlayer insulating layer 121 may include a flowable oxide (FOX), tonen silazen (TOSZ), an undoped silica glass (USG), a borosilica glass (BSG), a phosphosilaca glass (PSG), a borophosphosilica glass (BPSG), a plasma enhanced tetraethylorthosilicate (PETEOS), a fluoride silicate glass (FSG), a high density plasma (HDP) oxide, a plasma enhanced oxide (PEOX), a flowable chemical vapor deposition (CVD) (FCVD) oxide, or combinations thereof. At least a portion of the first interlayer insulating layer 121 surrounding the first interconnection structure 125 may be composed of a low dielectric layer. The first interlayer insulating layer 121 may be formed using a CVD process, a FCVD process, or a spin coating process.

The first interconnection structure 125 may be disposed in the first interlayer insulating layer 121. The first interconnection structure 125 may be formed as a multi-layer structure including a plurality of interconnection patterns and a plurality of vias formed of, for example, aluminum (Al), gold (Au), cobalt (Co), copper (Cu), nickel (Ni), lead (Pb), tantalum (Ta), tellurium (Te), titanium (Ti), tungsten (W), or a combination thereof. A barrier film containing titanium (Ti), titanium nitride (TiN), tantalum (Ta), or tantalum nitride (TaN) may be disposed between the first interconnection structure 125 or/and via and the first interlayer insulating layer 121. The first interconnection structure 125 may be electrically connected to the conductive region 112 and/or the individual devices ID by an interconnection portion 123 (e.g., a contact plug). The first interconnection structure 125 may include first front pads 125P. The first front pads 125P may correspond to connection pads of a bare chip. The first front pads 125P may include, for example, aluminum (Al) or an aluminum (Al) alloy, but embodiments are not limited thereto. The first front pads 125P may be arranged on the first front surface FS1. That is, the first front pads 125P may be arranged on the first interlayer insulating layer 121 that contacts the first front surface FS1. In one or more embodiments, the first front pads 125P may directly contact the first front surface FS1.

The second semiconductor chip 200 may include a second substrate 210, a second circuit layer 220, and through-electrodes 230. In one or more embodiments, a plurality of second semiconductor chips 200 may be provided. For example, the second semiconductor chip 200 may be provided as two or more semiconductor chips arranged horizontally below the first semiconductor chip 100. Additionally, the second semiconductor chip 200 may be provided as a plurality of semiconductor chips stacked in a vertical direction (Z-axis direction) below the first semiconductor chip 100.

The second semiconductor chip 200 may include components that may be substantially the same as or similar to those of the first semiconductor chip 100. Therefore, identical or similar components may be referred to by identical or similar reference numerals and terms, and repeated descriptions below may be omitted. For example, the second substrate 210, a second interlayer insulating layer 221, a second interconnection structure 225, and second front pads 225P may have the same or similar characteristics as the first substrate 110, the first interlayer insulating layer 121, the first interconnection structure 125, and the first front pads 125P, described above. As such, corresponding components may be indicated with similar reference numbers, and repeated descriptions may be be omitted.

The second semiconductor chip 200 may be arranged such that the second front pads 225P face the first front pads 125P of the first semiconductor chip 100. The second front pads 225P may be arranged on a second front surface FS2 of the second substrate 210. That is, the second front pads 225P may be arranged on the second interlayer insulating layer 221 that contacts the second front surface FS2 of the second substrate 210. In one or more embodiments, the second front pads 225P may directly contact the second front surface FS2. The second front pads 225P may include, for example, aluminum (Al) or an aluminum (Al) alloy, but embodiments are not limited thereto.

The through-electrodes 230 may electrically connect the second front pads 225P and rear pads 230P of the second semiconductor chip 200. The through-electrodes 230 may extend from the second front surface FS2 to a second rear surface BS2 of the second substrate 210. The second semiconductor chip 200 may be electrically connected to the connection bumps 305 through the through-electrodes 230. The through-electrodes 230 may include a via plug 235 and a side barrier film 231 surrounding a side surface of the via plug 235. The via plug 235 may include, for example, tungsten (W), titanium (Ti), aluminum (Al), or copper (Cu), and may be formed by a plating process, a PVD process, or a CVD process. The side barrier film 231 may include titanium (Ti), titanium nitride (TiN), tantalum (Ta), or tantalum nitride (TaN), and may be formed by a plating process, a PVD process, or a CVD process. A side insulating film 233 containing an insulating material such as silicon oxide, silicon nitride, silicon oxynitride, etc. (e.g., high aspect ratio process (HARP) oxide) may be formed between the through-electrodes 230 and the second substrate 210.

The front cover layer 101 may entirely or at least partially cover the first front surface FS1 of the first semiconductor chip 100. The front cover layer 101 may at least partially cover the first interlayer insulating layer 121, may expose at least a portion of each of the first front pads 125P, and may have openings through which the first connection pillars 105 are disposed. The front cover layer 101 may be formed to fill a space between the first connection pillars 105, the space between the first connection pillars 105 being between the first semiconductor chip 100 and the second semiconductor chip 200, and to surround a side surface, respectively. A thickness of the front cover layer 101 may be greater than or substantially equal to a height of the first connection pillars 105, but embodiments are not limited thereto.

The front cover layer 101 may minimize heat loss during a thermocompression bonding process to improve efficiency of a bonding process between the first semiconductor chip 100 and the second semiconductor chip 200. The thermal conductivity of the front cover layer 101 may be smaller than the thermal conductivity of the first interlayer insulating layer 121 and the thermal conductivity of the first substrate 110. For example, the thermal conductivity of the first substrate 110 may be about 150 W/m·K or more at room temperature, the thermal conductivity of the first interlayer insulating layer 121 may be about 1 W/m·K or more at room temperature, and the thermal conductivity of the front cover layer 101 may be less than about 1 W/m·K at room temperature. The front cover layer 101 may include a polymer organic material having relatively low thermal conductivity. The front cover layer 101 may include a photosensitive resin, for example a photoimageable dielectric (PID), having thermal conductivity of about 0.1 W/m·K to about 0.9 W/m·K, about 0.1 W/m·K to about 0.8 W/m·K, about 0.1 W/m·K to about 0.7 W/m·K, about 0.1 W/m·K to about 0.6 W/m·K, about 0.1 W/m·K to about 0.5 W/m·K, about 0.1 W/m·K to about 0.4 W/m·K, etc., at room temperature, but embodiments not limited thereto.

The first connection pillars 105 may be respectively disposed in openings of the front cover layer 101, and may be electrically connected to the first front pads 125P. According to one or more embodiments, the first connection pillars 105 may include a first group of first connection pillars 105a connected to the second connection pillars 205, and a second group of first connection pillars 105b connected to the first through-vias 310. The first group of first connection pillars 105a may be aligned with the second connection pillars 205. The first group of first connection pillars 105a may be arranged in a region that is over the second semiconductor chip 200. The second group of first connection pillars 105b may be arranged in a region outside of the sides of the second semiconductor chip 200.

Each of the first connection pillars 105 may include a first plating layer 105P, as well as a first seed layer 105S disposed between the first plating layer 105P and the first front pads 125P corresponding thereto. The first seed layer 105S may also be disposed between the first plating layer 105P and the front cover layer 101. For example, the first seed layer 105S may extend conformally along upper and side surfaces of the first plating layer 105P. The first plating layer 105P may include any one of copper (Cu), nickel (Ni), titanium (Ti), aluminum (Al), gold (Au), or silver (Ag), or an alloy thereof. The first seed layer 105S may include titanium (Ti), tantalum (Ta), or an alloy thereof, but the present inventive concept is not limited thereto.

The adhesive film layer 201 may surround each of the side surfaces of the second connection pillars 205 between the first semiconductor chip 100 and the second semiconductor chip 200, and may fill a space between the second connection pillars 205. The adhesive film layer 201 may support and secure the first semiconductor chip 100 and the second semiconductor chip 200. The adhesive film layer 201 may include, for example, any type of polymer film capable of performing a heat compression process. The adhesive film layer 201 may include a different type of material from the front cover layer 101. The adhesive film layer 201 may be a film containing a non-photosensitive resin, such as a non-conductive film (NCF), but embodiments are not limited thereto. The adhesive film layer 201 may have a fillet portion protruding out of the second semiconductor chip 200.

The second connection pillars 205 may be respectively disposed on the second front pads 225P. The second connection pillars 205 may be aligned with the first group of first connection pillars 105a corresponding thereto. Each of the second connection pillars 205 may include a pillar portion 205a and a solder portion 205b. The pillar portion 205a may include a second plating layer 205Pa and a second seed layer 205Sa. The second seed layer 205Sa may be disposed between the second plating layer 205Pa and the second front pads 225P corresponding thereto. For example, the second seed layer 205Sa may conformally extend along a lower surface of the second plating layer 205Pa. The second plating layer 205Pa may include any one of copper (Cu), nickel (Ni), titanium (Ti), aluminum (Al), gold (Au), or silver (Ag), or an alloy thereof. The second seed layer 205Sa may include titanium (Ti), tantalum (Ta), or an alloy thereof, but embodiments are not limited thereto. The solder portion 205b may be disposed between the pillar portion 205a and the first connection pillars 105 corresponding thereto. The solder portion 205b may include a low melting point metal, for example, tin (Sn) or an alloy containing tin (Sn) (Sn—Ag—Cu). A height of each of the first connection pillars 105 may be smaller than a height of each of the second connection pillars 205 or a height of the pillar portion 205a.

The first through-vias 310 may be disposed in a peripheral portion of the second semiconductor chip 200. The first through-vias 310 may pass through the molded layer 330 on at least one side of the second semiconductor chip 200. The first through-vias 310 may be disposed on the second group of first connection pillars 105b. The first through-vias 310 may be electrically connected to the first semiconductor chip 100 through the second group of first connection pillars 105b. The first through-vias 310 may include any one of copper (Cu), nickel (Ni), titanium (Ti), aluminum (Al), gold (Au), or silver (Ag), or an alloy thereof.

The molded layer 330 may seal the second semiconductor chip 200 on the first front surface FS1 of the first semiconductor chip 100. The molded layer 330 may surround or partially surround the second group of first connection pillars 105b and the second rear surface BS2 of the second semiconductor chip 200. The molded layer 330 may be formed to surround side surfaces of the first through-vias 310 and side surfaces of the second semiconductor chip 200. The molded layer 330 may include, for example, a thermosetting resin such as an epoxy resin, a thermoplastic resin such as polyimide, or a prepreg impregnated therein with an inorganic filler, Ajinomoto build-up film (ABF), an FR-4, bismaleimide triazine (BT), an epoxy molding compound (EMC).

The connection bumps 305 may be disposed on the molded layer 330, and may be electrically connected to the first through-vias 310 and the through-electrodes 230 of the second semiconductor chip 200. The semiconductor package 10A may be connected to an external device such as a module substrate, a main board, etc. through the connection bumps 305. For example, the connection bumps 305 may include a pillar portion 305a and a solder portion 305b. The pillar portion 305a may include copper (Cu) or an alloy of copper (Cu), and the solder portion 305b may include a low melting point metal, for example, tin (Sn) or an alloy containing tin (Sn) (Sn—Ag—Cu). The connection bumps 305 may include only the pillar portion 305a or may include only the solder portion 305b. The protective layer 301 may at least partially surround the connection bumps 305 below the molded layer 330. The protective layer 301 may protect the connection bumps 305 from external physical/chemical damage. The protective layer 301 may be formed using a prepreg, an ABF, an FR-4, BT, a PID, a photo-solder resist, etc. The protective layer 301 may be formed to cover a lower surface of the pillar portion 305a of the connection bumps 305, or may be omitted.

The semiconductor package 10A may further include second through-vias 320. The second through-vias 320 may pass through the molded layer 330 on the second rear surface BS2 of the second semiconductor chip 200, and may electrically connect the through-electrodes 230 and the connection bumps 305. The second through-vias 320 may include any one of copper (Cu), nickel (Ni), titanium (Ti), aluminum (Al), gold (Au), or silver (Ag), or an alloy thereof.

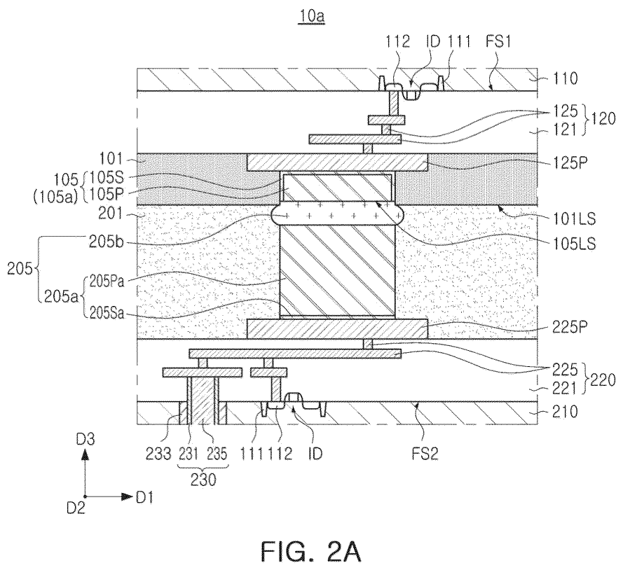

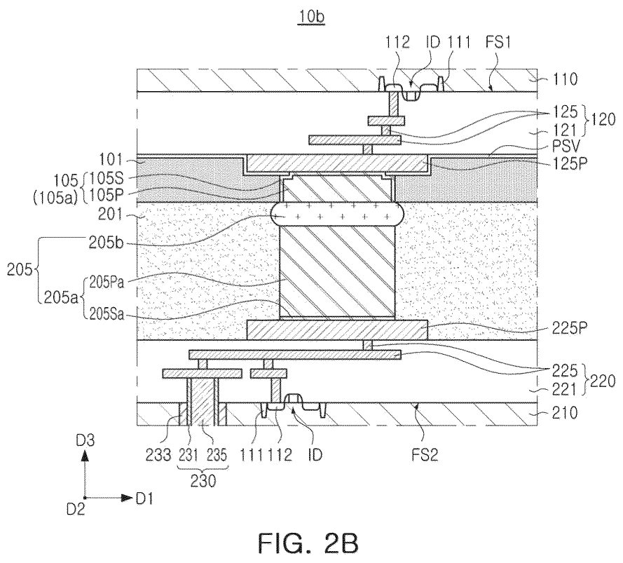

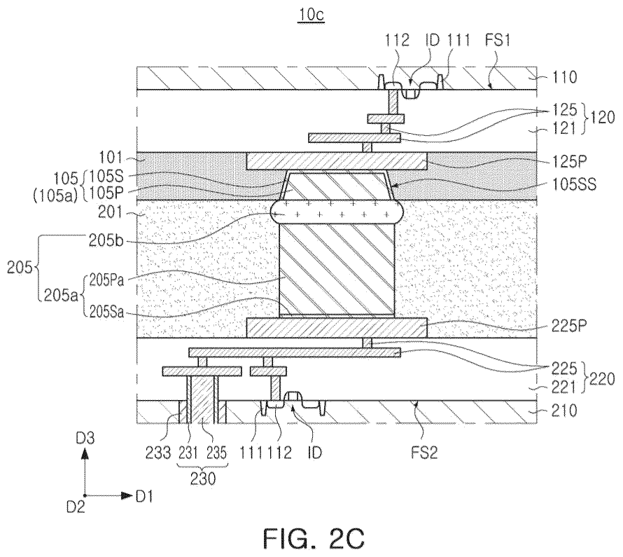

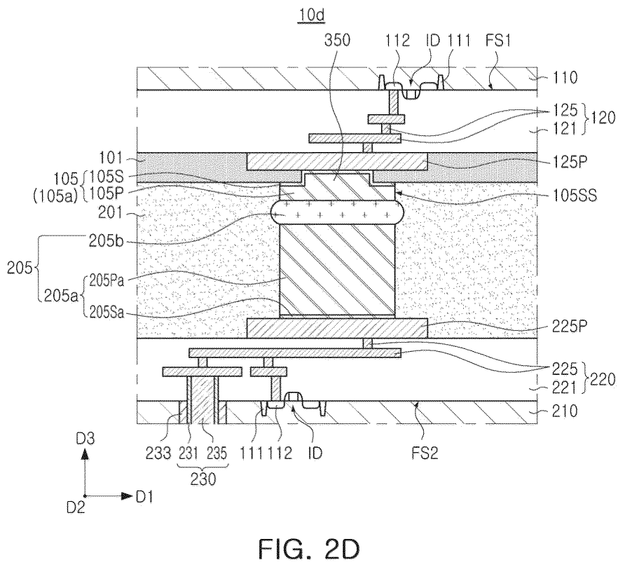

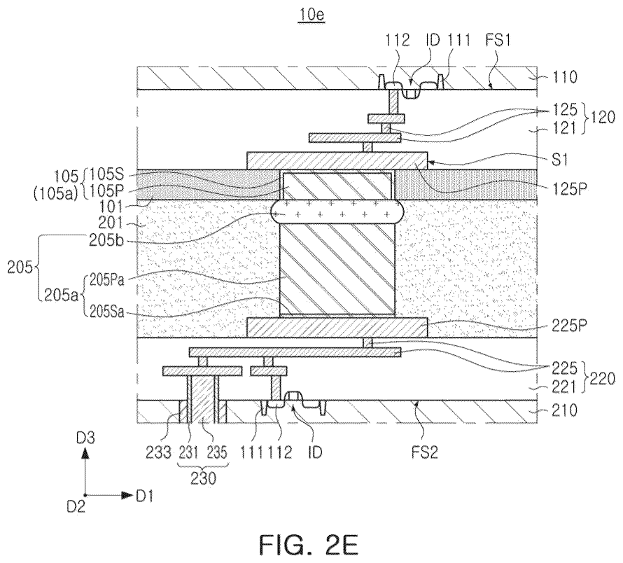

FIGS. 2A to 2E are partially enlarged views illustrating a semiconductor package according to one or more embodiments. FIGS. 2A to 2E are views illustrating example modifications of the components illustrated in FIG. 1C.

Referring to FIG. 2A, in a semiconductor package 10a, a thickness of a front cover layer 101 may be greater than a height of a first connection pillars 105. A lower surface 101LS of the front cover layer 101 may have a step difference from a lower surface 105LS of the first connection pillars 105. For example, a distance from a first front pads 125P to the lower surface 101LS of the front cover layer 101 may be greater than a distance from the first front pads 125P to the lower surface 105LS of the first connection pillars 105. The thickness of the front cover layer 101 may be changed depending on thermocompression process conditions.

Referring to FIG. 2B, in a semiconductor package 10b, a first semiconductor chip 100 may further include a passivation layer PSV. The passivation layer PSV may be disposed between a front cover layer 101 and a first interlayer insulating layer 121, and may cover at least a portion of first front pads 125P. The passivation layer PSV may extend along a side surfaces and at least a portion of an upper surface of the first front pads 125P. A thickness of the passivation layer PSV may be smaller than a thickness of the front cover layer 101. The passivation layer PSV may include at least one of silicon oxide or silicon nitride. The passivation layer PSV may include a polymer such as, for example, a photo-solder resist (PSR).

Referring to FIG. 2C, in a semiconductor package 10c, first connection pillars 105 may have a shape with an inclined side surface. For example, a side surface 105SS of the first connection pillars 105 may be tapered toward first front pads 125P corresponding thereto. The first connection pillars 105 may be tapered such that an upper width adjacent to the first front pads 125P may be smaller than a lower width adjacent to second connection pillars 205. A taper direction of the first connection pillars 105 may be determined depending on a type of polymer resin forming a front cover layer 101.

Referring to FIG. 2D, in a semiconductor package 10d, first connection pillars 105 may protrude onto a front cover layer 101. A first plating layer 105P of the first connection pillars 105 may include a via portion 350 passing through a portion of the front cover layer 101 and connected to first front pads 125P. A first seed layer 105S may be disposed between the first plating layer 105P and the front cover layer 101, as well as between the first plating layer 105P and the first front pads 125P corresponding thereto. A side surface 105SS of the first connection pillars 105 may be exposed from the front cover layer 101.

Referring to FIG. 2E, in a semiconductor package 10e, first front pads 125P may be buried in a first interlayer insulating layer 121. The first interlayer insulating layer 121 may be formed to surround a side surface S1 of the first front pads 125P. A lower surface of the first interlayer insulating layer 121 may be substantially coplanar with a lower surface of the first front pads 125P.

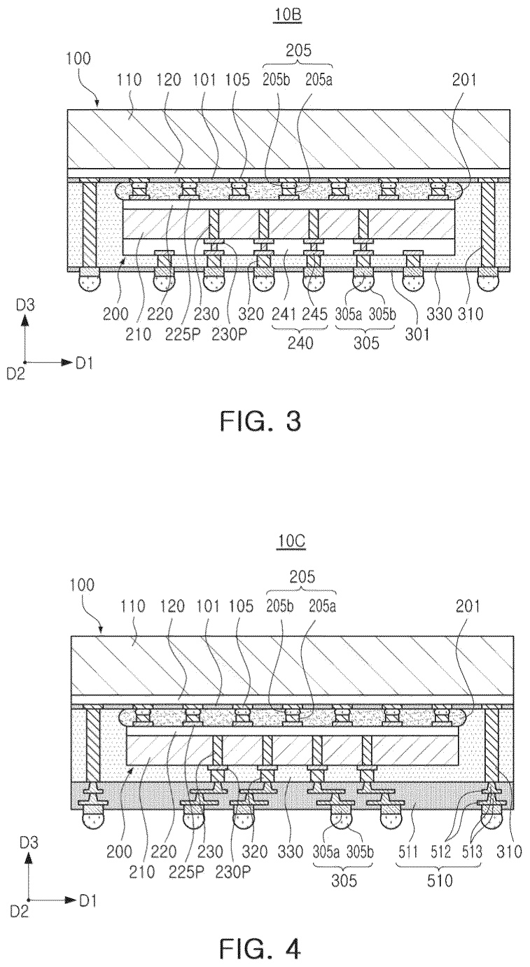

FIG. 3 is a cross-sectional view illustrating a semiconductor package 10B according to one or more embodiments.

Referring to FIG. 3, a semiconductor package 10B of one or more embodiments may have the same or similar characteristics to those described with reference to FIGS. 1A to 2E, except that a second semiconductor chip 200 further includes a rear redistribution layer 240. The rear redistribution layer 240 may redistribute through-electrodes 230 of the second semiconductor chip 200, and may electrically connect the same to connection bumps 305 or second through-vias 320. The rear redistribution layer 240 may include a rear insulating layer 241 and a rear redistribution structure 245. The rear redistribution structure 245 may include a conductive via and a conductive pattern connected to second rear pads 230P. The rear redistribution structure 245 may include a greater number of vias and patterns. The rear insulating layer 241 may include silicon oxide, silicon nitride, etc. The rear insulating layer 241 may include a photosensitive resin such as PID.

FIG. 4 is a cross-sectional view illustrating a semiconductor package 10C according to one or more embodiments.

Referring to FIG. 4, a semiconductor package 10C of one or more embodiments may have the same or similar characteristics to those described with reference to FIGS. 1A to 3 except that a redistribution structure 510 is further included. The redistribution structure 510 may be disposed between a molded layer 330 and connection bumps 305, and may redistribute and connect first through-vias 310 and through-electrodes 230 of a second semiconductor chip 200 (or second through-vias 320) to the connection bumps 305. In this manner, the redistribution structure 510 may be introduced to design layout of the connection bumps 305 in various manners. The redistribution structure 510 may include an insulating material layer 511, a redistribution pattern layer 512, and a redistribution via 513.

The insulating material layer 511 may be formed using a dielectric material such as silicon oxide, silicon nitride, silicon oxynitride, etc., or a photosensitive resin such as PID. The insulating material layer 511 may be formed as a plurality of layers depending on the number of layers of the redistribution pattern layer 512. Depending on a process, a boundary between at least a portion of the plurality of insulating material layers 511 may not be clear. According to one or more embodiments, a pillar portion 305a of the connection bumps 305 may be exposed from the insulating material layer 511, and a protective layer (301 in FIG. 1A) may be formed below the redistribution structure 510 to protect the connection bumps 305.

The redistribution pattern layer 512 may include, for example, a metal material including copper (Cu), aluminum (Al), silver (Ag), tin (Sn), gold (Au), nickel (Ni), lead (Pb), titanium (Ti), or alloys thereof. The redistribution pattern layer 512 may include, for example, a ground pattern, a power pattern, and a signal pattern. The signal pattern may transmit a data signal transmitted from the first semiconductor chip 100 and the second semiconductor chip 200 to the outside, or may transmit a data signal transmitted from the outside to the first semiconductor chip 100 and the second semiconductor chip 200. The redistribution pattern layer 512 may be formed as more or fewer layers than illustrated in the drawing.

The redistribution via 513 may extend vertically within the insulating material layer 511, and may be connected to the redistribution pattern layer 512. The redistribution via 513 may be formed as a filled via in which an internal space of a via hole is filled with a metal material or a conformal via in which a metal material is formed along an inner wall of a via hole. The redistribution via 513 may be integrated with the redistribution pattern layer 512, but embodiments are not limited thereto. The redistribution via 513 may be formed in a greater number of layers than illustrated, in correspondence with the redistribution pattern layer 512.

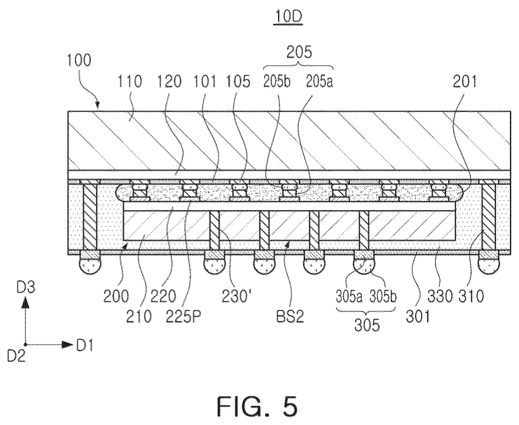

FIG. 5 is a cross-sectional view illustrating a semiconductor package 10D according to one or more embodiments.

Referring to FIG. 5, a semiconductor package 10D of one or more embodiments may have the same or similar characteristics to those described with reference to FIGS. 1A to 4, except that through-electrodes 230′ protrude from a rear surface BS2 of a second substrate 210. The through-electrodes 230′ may pass through the second substrate 210 to extend into an internal space of a molded layer 330. A portion of the side surface of the through-electrodes 230′ may be surrounded by the molded layer 330. The through-electrodes 230′ may be directly connected to connection bumps 305. In this manner, second through-vias (320 in FIG. 1A) may be omitted, and a manufacturing process may be further simplified.

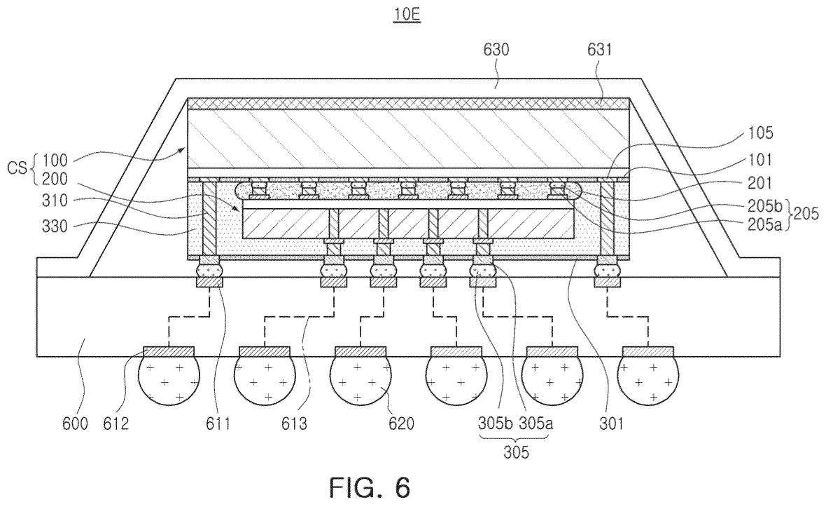

FIG. 6 is a cross-sectional view illustrating a semiconductor package 10E according to one or more embodiments.

Referring to FIG. 6, a bonding structure CS, a wiring board 600, and a heat dissipation structure 630 may be included. The bonding structure CS may include a first semiconductor chip 100, a second semiconductor chip 200, a front cover layer 101, etc., and may be a package structure having the same or similar characteristics to those described with reference to FIGS. 1A to 5.

The wiring board 600 may be a support board on which the bonding structure CS is mounted, and may be a board for a semiconductor package, such as a printed circuit board (PCB), a ceramic board, or a tape wiring board. The wiring board 600 may include a lower pad 612, an upper pad 611, and a wiring circuit 613 electrically connecting the lower pad 612 and the upper pad 611. A body of the wiring board 600 may include a different material, depending on a type of board. For example, when the wiring board 600 is a PCB, the wiring board 600 may be a body copper clad laminate or a wiring layer additionally stacked on one surface or both surfaces of the copper clad laminate. The upper pad 611, the lower pad 612, and the wiring circuit 613 may form an electrical path connecting lower and upper surfaces of the wiring board 600. An external connection bump 620 connected to the lower pad 612 may be disposed on the lower surface of the wiring board 600. The external connection bump 620 may include tin (Sn), indium (In), bismuth (Bi), antimony (Sb), copper (Cu), silver (Ag), zinc (Zn), lead (Pb), and/or alloys thereof.

The heat dissipation structure 630 may be disposed to cover an upper portion of the bonding structure CS. The heat dissipation structure 630 may be attached to the wiring board 600 using an adhesive. The adhesive may use a thermally conductive adhesive tape, a thermally conductive grease, a thermally conductive adhesive, etc. The heat dissipation structure 630 may be attached to the upper portion of the bonding structure CS through a heat transfer material layer 631. The heat transfer material layer 631 may include, for example, a thermally conductive adhesive tape, a thermally conductive grease, a thermally conductive adhesive, etc.

The heat dissipation structure 630 may include a conductive material with excellent thermal conductivity. For example, the heat dissipation structure 630 may include metal or a metal alloy containing gold (Au), silver (Ag), copper (Cu), iron (Fe), etc., or a thermally conductive material such as graphite, graphene, etc. The heat dissipation structure 630 may have a shape different from that illustrated in the drawing. For example, the heat dissipation structure 630 may have a shape that covers only an upper surface of the bonding structure CS.

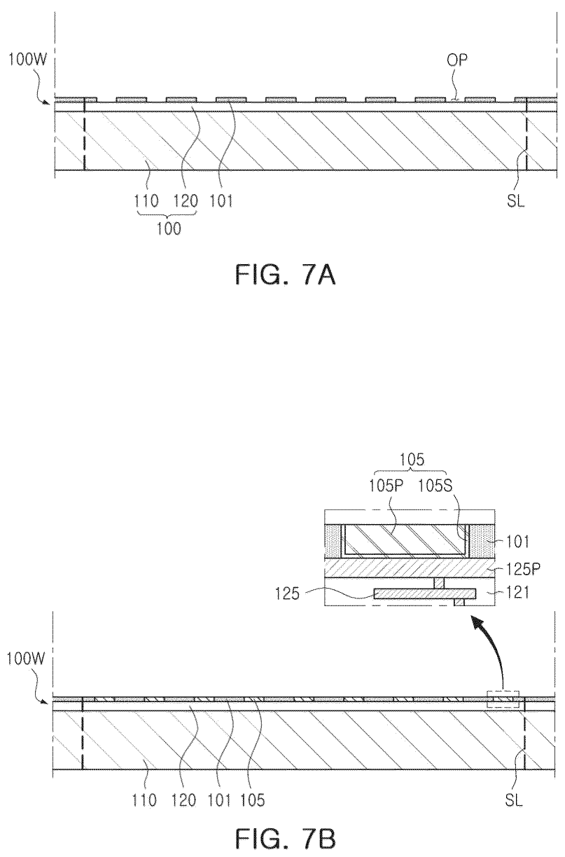

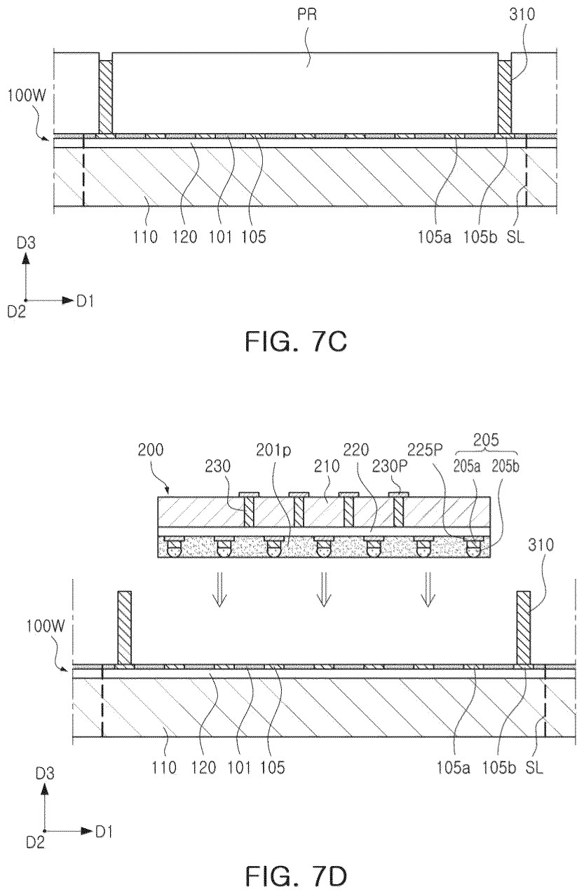

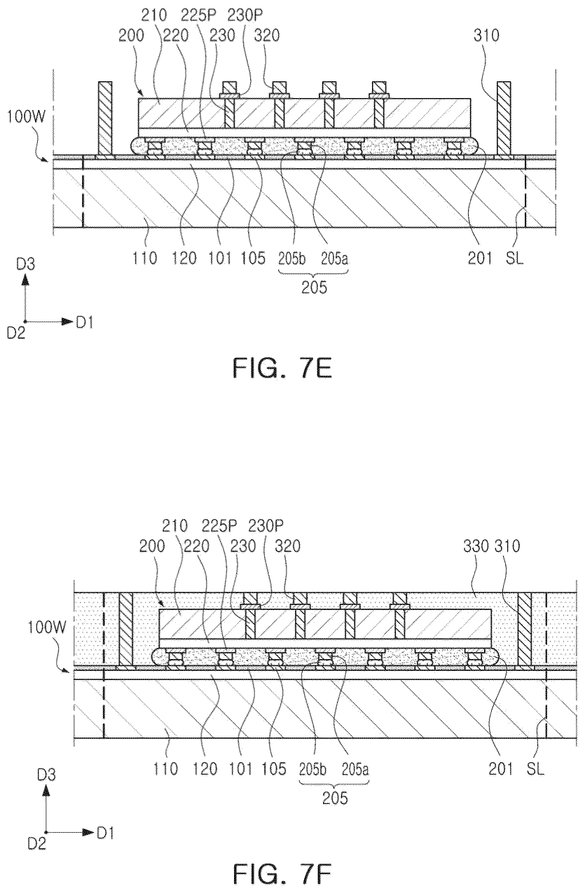

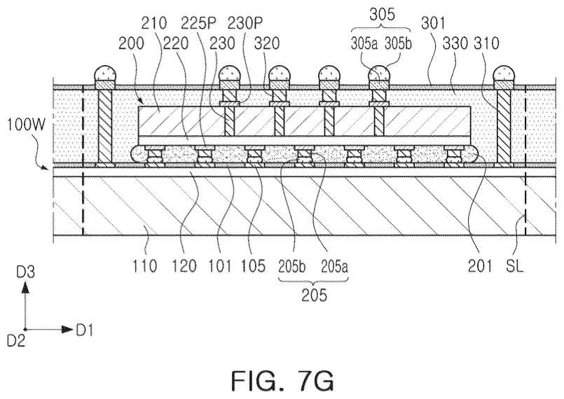

FIGS. 7A to 7G are views illustrating a process of manufacturing the semiconductor package according to one or more embodiments. FIGS. 7A to 7G may illustrate a process of forming the semiconductor package 10A of FIGS. 1A-1C, although embodiments are not limited thereto.

Referring to FIG. 7A, a semiconductor wafer 100W may be prepared. The semiconductor wafer 100W may include a plurality of first semiconductor chips 100 separated by a scribe line SL. The semiconductor wafer 100W may include a first substrate 110 and a first circuit layer 120. The semiconductor wafer 100W may be disposed on a wafer carrier such that the first circuit layer 120 faces in an upward direction.

A front cover layer 101 may be formed on the semiconductor wafer 100W. The front cover layer 101 may be provided on an upper surface of the semiconductor wafer 100W and may include openings OP. The front cover layer 101 may be formed by exposing and shaping a photosensitive resin such as PID. In one or more embodiments, the front cover layer 101 may entirely cover the upper surface of the semiconductor wafer 100W.

Referring to FIG. 7B, first connection pillars 105 may be formed on the semiconductor wafer 100W. The first connection pillars 105 may be formed in the openings (OP in FIG. 7A) of the front cover layer 101. The first connection pillars 105 may be formed on first front pads 125P. The first connection pillars 105 may include a first seed layer 105S and a first plating layer 105P. The first seed layer 105S may include metal such as titanium (Ti), and may be formed using, for example, a PVD process. The first plating layer 105P may include metal such as copper (Cu), and may be formed by a plating process using the first seed layer 105S. The first connection pillars 105 may be formed to have a height, equal to or smaller than a thickness of the front cover layer 101.

Referring to FIG. 7C, first through-vias 310 may be formed. The first through-vias 310 may be formed on a second group of first connection pillars 105b. The first through-vias 310 may include metal such as copper (Cu), and may be formed to have a post shape with a predetermined height using a patterned photosensitive material layer PR. Thereafter, the photosensitive material layer PR may be removed by performing an ashing process.

Referring to FIG. 7D, a second semiconductor chip 200 may be attached to the semiconductor wafer 100W. The second semiconductor chip 200 may include a second substrate 210, a second circuit layer 220, and through-electrodes 230. The second semiconductor chip 200 may be disposed on the semiconductor wafer 100W such that the second circuit layer 220 faces the first circuit layer 120 of the first semiconductor chip 100. Second connection pillars 205 may be formed on second front pads 225P of the second semiconductor chip 200. The second connection pillars 205 may be embedded in a preliminary adhesive layer 201p attached to the second semiconductor chip 200. The second connection pillars 205 may be aligned on a first group of first connection pillars 105a.

Referring to FIG. 7E, a thermal compression process may be performed to bond the second semiconductor chip 200 to the semiconductor wafer 100W. The heat compression process may be performed in a thermal atmosphere ranging from about 100° C. to about 300° C. However, a temperature of the thermal atmosphere is not limited to the above-mentioned range, and may be changed. The front cover layer 101 may minimize heat loss emitted through the semiconductor wafer 100W, thereby keeping a temperature of a stage in which a thermocompression bonding process is performed on an appropriate level (e.g., about 70° C. to about 130° C.).

Thereafter, second through-vias 320 may be formed on the second semiconductor chip 200. The second through-vias 320 may be disposed on rear pads 230P of the second semiconductor chip 200. The second through-vias 320 may be formed by a similar process to the first through-vias 310. The second through-vias 320 may include metal such as copper (Cu), and may be formed using a plating process or the like.

Referring to FIG. 7F, a molded layer 330 may be formed on the semiconductor wafer 100W. The molded layer 330 may be formed by applying and curing EMC. The molded layer 330 may seal the second semiconductor chip 200, the first through-vias 310, and the second through-vias 320. The molded layer 330 may be subjected to a planarization process (e.g., grinding process) to expose the first through-vias 310 and the second through-vias 320. Upper ends of the first and second through-vias 310 and 320 may be exposed from an upper surface of the molded layer 330.

Referring to FIG. 7G, a protective layer 301 and connection bumps 305 may be formed on the molded layer 330. The protective layer 301 may be formed using, for example, a photosensitive resin such as PID or PSR. The connection bumps 305 may include, but are not limited to, a pillar portion 305a and a solder portion 305b. Thereafter, unit packages may be separated from each other by performing a cutting process along the scribe line SL.

According to one or more embodiments, a front cover layer preventing heat loss in a thermocompression process may be introduced to provide a semiconductor package having improved efficiency of a manufacturing process.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package comprising:
a first semiconductor chip comprising:
a first substrate having a first front surface and a first rear surface;
first front pads;
a first interlayer insulating layer between the first front pads and the first substrate; and
a first interconnection structure in the first interlayer insulating layer and connected to the first front pads;
a front cover layer on the first interlayer insulating layer and comprising openings respectively exposing at least a portion of each of the first front pads;
first connection pillars respectively in the openings of the front cover layer and respectively connected to the first front pads;
a second semiconductor chip comprising:
a second substrate having a second front surface and a second rear surface;
second front pads facing a first group of the first connection pillars; and
through-electrodes in the second substrate and connected to the second front pads;
second connection pillars respectively on the second front pads and respectively connected to the first connection pillars of the first group of first connection pillars;
an adhesive film layer disposed between the first semiconductor chip and the second semiconductor chip and at least partially surrounding the second connection pillars;
a molded layer at least partially covering a second group of the first connection pillars and the second rear surface of the second semiconductor chip;
first through-vias in the molded layer and on at least one side of the second semiconductor chip, the first through-vias respectively on the first connection pillars of the second group of the first connection pillars; and
connection bumps disposed on the molded layer and electrically connected to the first through-vias and the through-electrodes of the second semiconductor chip,
wherein a thermal conductivity of the front cover layer is smaller than a thermal conductivity of the first interlayer insulating layer and a thermal conductivity of the first substrate.

2. The semiconductor package of claim 1, wherein each of the first connection pillars comprises a first plating layer, and a first seed layer between the first plating layer and a first front pad corresponding the first seed layer, and between the first plating layer and the front cover layer,
wherein the second connection pillars comprise pillar portions respectively on the second front pads, and solder portions respectively between the pillar portions and the first connection pillars, and
wherein each of the pillar portions comprises a second plating layer and a second seed layer between the second plating layer and a second front pad corresponding to the second seed layer.

3. The semiconductor package of claim 2, wherein the first plating layer and the second plating layer comprise copper (Cu) or a copper (Cu) alloy, and
wherein the first seed layer and the second seed layer comprise titanium (Ti) or a titanium (Ti) alloy.

4. The semiconductor package of claim 3, wherein the first front pads and the second front pads comprise aluminum (Al) or an aluminum (Al) alloy.

5. The semiconductor package of claim 2, wherein a height of each of the first connection pillars is smaller than a height of respective pillar portions of the second connection pillars.

6. The semiconductor package of claim 1, wherein the thermal conductivity of the front cover layer is less than 1 W/m·K.

7. The semiconductor package of claim 1, wherein the front cover layer comprises a photosensitive resin, and
wherein the adhesive film layer comprises a non-photosensitive resin.

8. The semiconductor package of claim 1, wherein the first substrate comprises a semiconductor element comprising silicon or germanium, or a compound semiconductor comprising silicon carbide (SiC), gallium arsenide (GaAs), indium arsenide (InAs), or indium phosphide (InP), and
wherein the first interlayer insulating layer comprises at least one of silicon oxide (SiO) and silicon nitride (SiN).

9. The semiconductor package of claim 1, wherein a thickness of the front cover layer is greater than or equal to a height of each of the first connection pillars.

10. The semiconductor package of claim 1, wherein the first semiconductor chip further comprises a passivation layer covering at least a portion of the first front pads, and between the front cover layer and the first interlayer insulating layer.

11. The semiconductor package of claim 10, wherein a thickness of the front cover layer is greater than a thickness of the passivation layer.

12. The semiconductor package of claim 10, wherein the passivation layer comprises at least one of silicon oxide and silicon nitride.

13. The semiconductor package of claim 1, wherein side surfaces of the first connection pillars are tapered toward respective first front pads.

14. The semiconductor package of claim 1, further comprising second through-vias in the molded layer and connecting the through-electrodes of the second semiconductor chip and the connection bumps.

15. The semiconductor package of claim 14, wherein the second semiconductor chip further comprises a rear redistribution layer connecting the through-electrodes and the second through-vias.

16. The semiconductor package of claim 1, further comprising a redistribution structure between the molded layer and the connection bumps and connecting the first through-vias and the through-electrodes to the connection bumps.

17. A semiconductor package comprising:
a first semiconductor chip comprising a first substrate having a first front surface and first front pads;
a second semiconductor chip comprising:
a second substrate having a second front surface;
second front pads facing the first front pads; and
through-electrodes in the second substrate and respectively connected to the second front pads;
first connection pillars respectively on the first front pads;
a front cover layer at least partially surrounding a side surface of each of the first connection pillars on the first front surface of the first semiconductor chip;
second connection pillars respectively on the second front pads and respectively connected to the first connection pillars;
an adhesive film layer at least partially surrounding a side surface of each of the second connection pillars on the second front surface of the second semiconductor chip;
a molded layer at least partially surrounding the second semiconductor chip on the first semiconductor chip; and
connection bumps respectively connected to the through-electrodes of the second semiconductor chip,
wherein a thermal conductivity of the front cover layer is less than 1 W/m·K.

18. The semiconductor package of claim 17, wherein the thermal conductivity of the front cover layer is in a range of 0.1 W/m·K to 0.5 W/m·K.

19. A semiconductor package comprising:
a first semiconductor chip comprising:
a first substrate;
first front pads;
an interlayer insulating layer between the first front pads and the first substrate; and
an interconnection structure in the interlayer insulating layer and connected to the first front pads;
a second semiconductor chip comprising a second substrate, and second front pads on the second substrate and facing the first front pads;
first connection pillars respectively on the first front pads;
a front cover layer filling a space between the first connection pillars;
second connection pillars respectively on the second front pads and respectively contacting the first connection pillars; and
an adhesive film layer filling a space between the second connection pillars,
wherein the interlayer insulating layer comprises a non-metallic inorganic material, and
wherein the front cover layer and the adhesive film layer comprise a polymer organic material.

20. The semiconductor package of claim 19, wherein the interlayer insulating layer comprises at least one of silicon oxide (SiO) and silicon nitride (SiN),
wherein the front cover layer comprises a photoimageable dielectric (PID), and
wherein the adhesive film layer comprises a non-conductive film (NCF).
